(19) United States
(12) Patent Application Publication
(10) Pub. No.: US 2004/0159490 A1
(43) Pub. Date: Aug. 19, 2004

(54) Compact loudspeaker and control switch assembly and method for installing and adjusting a loudspeaker in a partition

(76) Inventor: Bruce E. Marlin, Ennis, TX (US)

Correspondence Address: J. Andrew McKinney, Jr., Liniak, Berenato & White, LLC, Suite 240, 6550 Rock Spring Dr., Bethesda, MD, 20817, US

(21) Appl. No.: 10/769,812

(22) Filed: Feb. 3, 2004

Related U.S. Application Data
(60) Provisional application No. 60/444,481, filed on Feb. 3, 2003.

(51) Int. Cl. H05K 5/00

(52) U.S. Cl. 181/148

(57) ABSTRACT

A loudspeaker and switch assembly is adapted to require a reduced mounting space and incorporates a coaxially mounted switch for power selection having its shaft extending through the loudspeaker driver's pole piece. The switch is mounted to the back plate and the switch shaft runs through the pole piece so that the user can select power via a knob mounted on the proximal or front end of the switch of the loudspeaker dust cap. The power selection knob is used to turn the switch and select an input power level to the speaker, and the body of the knob also defines an axially symmetrical curvilinear or contoured solid shape which functions as an acoustic diffuser to increase the uniformity of the radiation pattern for higher frequencies which would otherwise be narrowly beamed into an area directly in front of the loudspeaker diaphragm.

### RELATED APPLICATION INFORMATION

This application is a continuation of and claims priority to U.S. provisional application serial No. 60/444,481, filed February 3^{rd}, 2003, the entire disclosure of which is incorporated herein by reference.

### BACKGROUND OF THE INVENTION

1. Field of the Invention

The present invention relates to loudspeakers to be mounted in ceilings, walls or other partitions for use in commercial, industrial or other sound systems or acoustic masking systems, such as, for example, business and commercial ceiling speaker systems.

2. Discussion of the Prior Art

Business and commercial sound systems often include ceiling speaker systems that are specified by consultants and installed by contractors. Desirable characteristics of ceiling speaker systems include smooth frequency response, even, wide coverage, sonically pleasing voicing and ease of installation and adjustment. Ceiling speaker systems have been specified for use in many business music and public address applications.

Installers and contractors have always sought ways to reduce installation time and to simplify the methods for making system tuning or balancing adjustments. Covering an area with even or consistent sound levels contributes to satisfying music and public address system performance. If there is uneven coverage, then occupants of the space are likely to be distracted by changes in sound quality or perceived loudness when moving about within the space.

Architects and designers of large office spaces have largely abandoned the practice of placing each desk in its own small office. Instead, modern office arrangements usually include large, spacious, open floors shared by many desks, thereby (theoretically) providing enhanced efficiency and an informal atmosphere. One drawback of the new open plan office design is that privacy of conversation formerly provided by smaller individual offices is lost, since the conversation between workers or over the telephone is readily overheard and may provide a distracting intrusion not appreciated by adjacent workers. Distractions such as operation of business machines, telephones ringing and other extraneous noises may tend to lower employee productivity. The open plan concept has gone beyond the office and is finding acceptance in hospital patient rooms where, again, privacy is lost.

It is well known to provide background noise generation systems for the purpose of masking conversations or other distracting noises. Several problems are confronted when attempting to design and install effective background noise masking systems, however.

The masking noise should be uniformly distributed throughout the space in order to achieve satisfactory masking results. Ideally, background masking noise is a broad spectrum, uniformly distributed, diffuse sound field of uniform intensity and is substantially imperceptible to those in the treated space. If the masking noise is not uniformly distributed or diffused throughout the work space, masking tends to be less effective in a first area and more effective in a second area; a person walking through a work space from the first area to the second area is subjected to different intensities of masking noise and thus is more likely to become conscious of and distracted by the masking noise. Because of this problem, masking systems employing loudspeakers radiating directly into the work space from the ceiling tend to require careful level matching, since uneven masking noise loudness tends to be particularly distracting.

There are prior art systems utilizing conventional loudspeakers installed in the plenum spaces above the ceiling to use plenum space as a mixing chamber for masking noise where, in theory, the masking noise from several loudspeakers mixes and then filters down uniformly through the ceiling and into the office space. Unfortunately, such installations tend to provide poor masking performance since the plenum is usually obstructed by duct work or the like and since the plenum may or may not be sufficiently acoustically reflective to provide adequate mixing. Insulated air conditioning ducts and other equipment in the plenum tends to interfere with distribution and mixing of the sound and provide poor mixing performance. By way of example, U.S. Pat. No. 3,985,957, to William R. Torn, discloses a structure including clusters of speakers mounted in the plenum above an office space. Each cluster has two cone diaphragm speakers in a prism-shaped cabinet symmetrically disposed about a vertical axis. The sound masking system of Torn requires that a plurality of clusters be employed to cover quiet regions, which may develop below a cluster. Torn's sound masking system requires that the plenum region be relatively free of obstructing materials which would tend to interfere with the reflecting and mixing of masking sound before propagation down through the ceiling tiles into the office space. Cone diaphragm loudspeakers of the prior art necessarily provide a substantially more directional output at higher frequencies (as compared to lower frequencies) thereby providing frequency dependent masking sound radiation. Since it is desired to provide a rather uniform pink or white noise for masking of conversation or the like, frequency dependent directionality or beaming may prove to be troublesome for an installer in trying to implement the sound masking system. Additionally, an installer working with the Torn system is required to suspend a plurality of loudspeaker cabinets having what may be very heavy loudspeaker drivers and a cabinet in the plenum space. As shown in Torn's FIGS. 1, 2 and 3, the loudspeaker cabinets or clusters are preferably suspended from the ceiling above the plenum by chain, cable or the like and so must be held in place while being installed.

Another problem with both masking system and music system loudspeakers of the prior art is that level adjustment mechanism controls are usually positioned on the back or side of the enclosure or back can, and so an installer, when balancing (or adjusting the levels of) several speakers for uniform coverage, must dis-install each speaker from its mount to select an appropriate sound level or power consumption setting, and then re-install the speaker in the ceiling; this process may have to be repeated as many speakers are adjusted. If the installer has to spend significant time on a ladder dis-installing and re-installing speaker enclosures in a ceiling, his or her desire to achieve an optimum balance for the system may diminish as his feet tire.

A speaker having a front-mounted control beside the speaker driver necessarily requires the entire enclosure and grill area to be enlarged to make room for the control (i.e., beside the speaker driver) and so the mounting space required is increased, possibly in a manner requiring an oddly shaped bezel or an awkwardly shaped opening in the ceiling.

There is a need, therefore, for an effective ceiling-mounted speaker providing a broad-band, diffused sound field and that is easily mounted in a small area.

### OBJECTS AND SUMMARY OF THE INVENTION

Accordingly, it is a primary object of the present invention to overcome the above mentioned difficulties by providing a compact ceiling mounted speaker which provides a broad-band, diffused sound field but is easily mounted by an installer.

Another object of the present invention is simplifying the process for installing and balancing (i.e., adjusting the relative levels of) several speakers radiating into a given space for uniform coverage.

The aforesaid objects are achieved individually and in combination, and it is not intended that the present invention be construed as requiring two or more of the objects to be combined, unless required by a claim.

The loudspeaker and switch assembly of the present invention is adapted to require a reduced mounting space and incorporates a coaxially mounted switch assembly for power selection having its shaft extending through the loudspeaker driver's pole piece. The switch is mounted to the back plate and the switch shaft runs through the pole piece so that the user can select power via a knob mounted on the proximal or front end of the switch of the loudspeaker dust cap.

The power selection knob has two functional roles, namely (1) to turn the switch shaft and select and input power level applied to the speaker, and (2) to define an axially symmetrical curvilinear or contoured solid “phase plug” like shape which functions as an acoustic diffuser to increase the uniformity of the radiation pattern for higher frequencies (which would otherwise be narrowly beamed into an area directly in front of the loudspeaker diaphragm). The enclosure or back can includes a removable cover adapted to receive rigid or flex conduit and a 4 pole detachable “phoenix” style connector allows easy pre-wiring and is convenient for daisy chaining additional speakers or subwoofers. “Press fit” grills are releaseably attachable to the front or proximal end of the enclosure and are contoured and finished to blend into contemporary architecture. An enhanced quality 70.7V/16W (or, for European std. applications, 100v) multi-tap internal transformer is used to minimize insertion loss and maintain low frequency response while providing increased output for higher SPL applications. Optionally, the loudspeaker driver includes a weather/UV resistant polypropylene cone with butyl rubber surround, contributing to even frequency response and coverage. The coaxial speaker/selector switch/tap indicator bracket assembly permits the footprint of the loudspeaker of the present invention to be identical to that of a standard speaker having the same driver diameter.

The tap selector switch is front mounted on the baffle assembly allowing easy system tuning, for maintaining even coverage throughout the space.

The above and still further objects, features and advantages of the present invention will become apparent upon consideration of the following detailed description of a specific embodiment thereof, particularly when taken in conjunction with the accompanying drawings, wherein like reference numerals in the various figures are utilized to designate like components.

### BRIEF DESCRIPTION OF THE DRAWINGS

FIG. 1 is a front view, in elevation, of the loudspeaker and switch assembly illustrating the switch selector knob, in accordance with the present invention.

FIG. 2 is a cross-sectional view, in elevation, taken along section lines A-A of the loudspeaker and switch assembly of FIG. 1, in accordance with the present invention.

FIG. 3 is an exploded perspective view of the loudspeaker and switch assembly of FIGS. 1 and 2, in accordance with the present invention.

FIG. 4 is a front-view, in elevation, of the loudspeaker driver and switch assembly used in the assembly of FIGS. 1, 2 and 3, in accordance with the present invention.

FIG. 5 is a cross-sectional view, in elevation, taken along section lines A-A of the loudspeaker driver of FIG. 4, in accordance with the present invention.

FIG. 6 is a left-side view, in elevation, of the complete assembly of FIG. 3, illustrating the side of the enclosure, in elevation, in accordance with the present invention.

FIG. 7 is a grill-side or front view, in elevation, of the speaker assembly of FIGS. 1-6, in accordance with the present invention.

FIG. 8 is a side cross sectional view, in elevation, of the loudspeaker assembly of FIGS. 1-7, illustrating the enclosure inserted in a partition aperture and held in place by the dog-leg or swing-out fasteners, in accordance with the present invention.

### DESCRIPTION OF THE PREFERRED EMBODIMENT

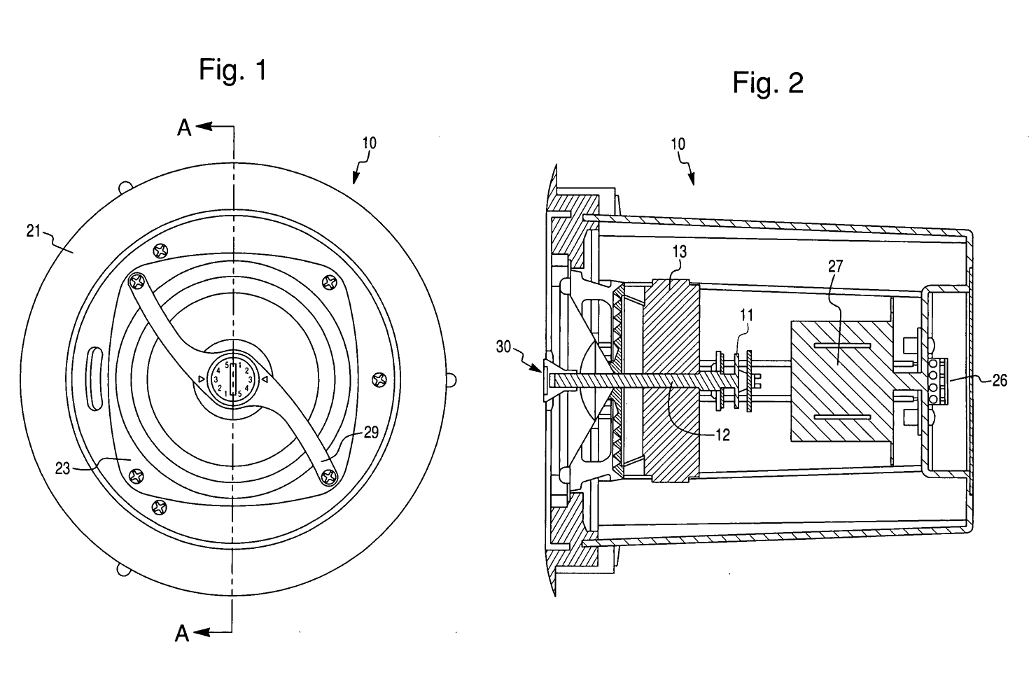

Referring now to FIGS. 1-8, loudspeaker and switch assembly 10 is adapted to require a reduced mounting space and incorporates a switch 11 for power selection having its shaft 12 extending through the loudspeaker driver's pole piece. Switch 11 is coaxially mounted to the driver back plate and an elongate switch shaft 12 runs through the center of the driver pole piece so that the user can select power via a knob mounted on the proximal or front end of the switch near the loudspeaker dust cap (as best seen in FIGS. 2 and 5).

As best seen in FIG. 2, power selector knob 30 not only acts to turn switch 11 and select an input power to the speaker 23, the body of knob 30 defines an axially symmetrical curvilinear or contoured solid shape which functions as an acoustic diffuser to increase the uniformity of the radiation pattern for higher frequencies which would otherwise be narrowly beamed into an area directly in front of the diaphragm of speaker 23.

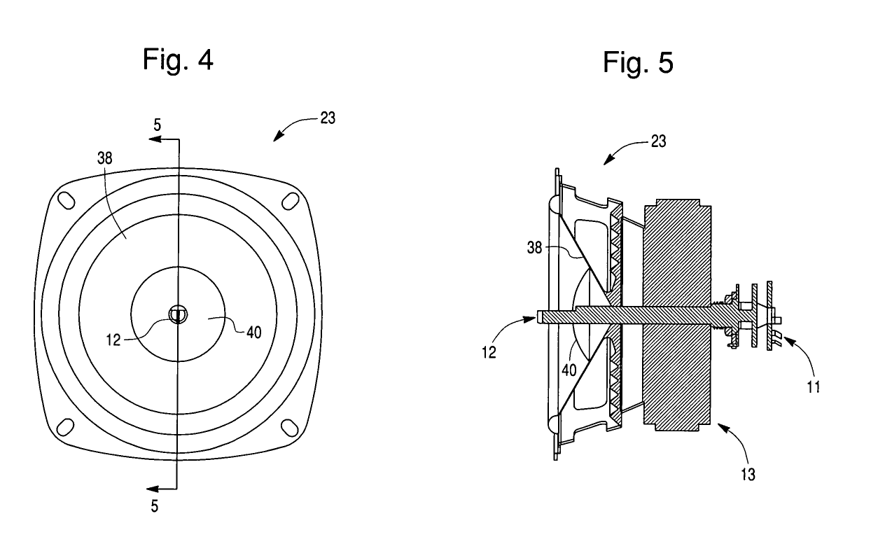

Referring now more particular to FIGS. 1, 2 & 3, loudspeaker and switch assembly 10 includes a substantially circular or annular proximal flange, baffle or sub plate 21 which carries a back can or enclosure 22 as well as a loudspeaker driver 23 which (as best seen in FIGS. 4 & 5) carries the coaxially mounted and aligned switch 11. Switch 11 includes a switch shaft 12 which is mounted substantially through the center of an axial bore in driver magnet assembly 13 penetrating the pole piece of the loudspeaker driver magnetic circuit so that the proximal end of switch shaft 12 projects through the loudspeaker driver diaphragm dust cap.

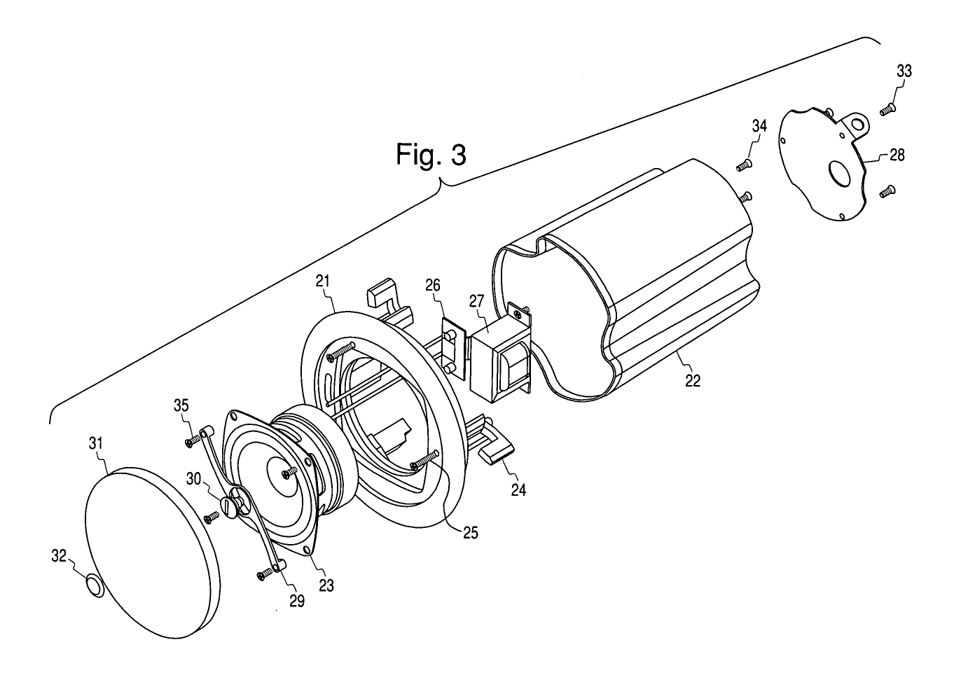

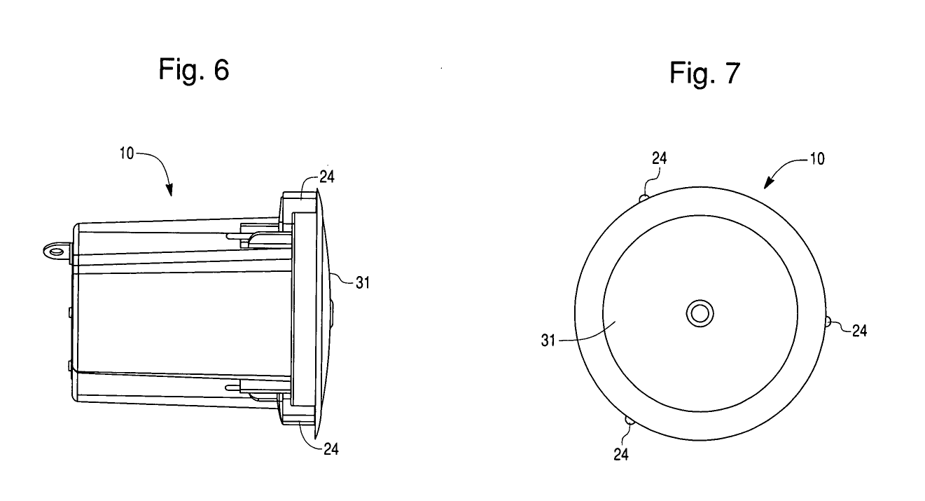

Enclosure or back can 22 can be cylindrical or, as shown in FIG. 3, can have a contoured shape to provide clearance for a plurality of dog-leg moveable or articulable swing-out fasteners 24 which are actuated by screws or fasteners 25 carried on proximal flange or baffle 21. Preferably, as best seen in FIGS. 6, 7 & 8, three equally spaced dog-leg fasteners are used to support the loudspeaker enclosure in place in a partition 50 (e.g., a ceiling, plenum boundary, wall or baffle) and, by actuating screws or fasteners 25, the user can easily mount loudspeaker and switch assembly 10 in a very confined spaced and later remove the loudspeaker and switch assembly 10 by swinging the dog-leg fasteners 25 to the side, thereby permitting the entire loudspeaker assembly to be withdrawn through a hole in partition 50.

Loudspeaker and switch assembly 10 is preferably connected to a sound system through a four pin Phoenix-style audio system connector 26, as best seen in FIGS. 2 & 3. Voice, music, pink noise or other signals can be used to drive loudspeaker driver 23, which is selectively connectable through switch 11 and transformer 27. Transformer 27 preferably includes a plurality of transformer taps to provide a wide variety of impedance or power level settings. Preferably, transformer 27 is an enhanced quality 70.7V/16W (or, for European std. applications, 100v) multi-tap internal transformer configured to minimize insertion loss and maintain good low frequency response while providing increased output for higher SPL applications.

The back can or enclosure 22 of loudspeaker and switch assembly 10 further includes a planar back cover 28 which is preferably adapted to receive conduit fittings or the like and includes at least one aperture adapted to receive a conduit fitting. Back cover 28 is preferably attached to back can 22 using a plurality of fasteners 33, preferably screws. In the preferred embodiment, a sticker or logo 32 is affixed to the center of grill 31, which is attached to the front of the speaker to protect the loudspeaker driver 23.

In the preferred embodiment illustrated in FIGS. 1-8, proximal selector knob 30 is used to actuate switch 11 which selects from among a plurality of taps in transformer 27 to select the input power provided to the speaker. The transformer primary windings are connected to electrical connector 26 and the selected transformer secondary winding is connected to the voice coil of driver 23. Selector or control knob 30 has a tapered, curvilinear or substantially conical shape, as best seen in FIG. 2, and so functions as an acoustical element altering the speaker's directivity at selected frequencies. Traditionally, at higher frequencies, cone shaped loudspeaker drivers tend to “beam” or become increasingly directional such that only listeners directly in front of the loudspeaker receive an acceptable amount of high frequency energy. The tapered or curvilinear shape of selector knob 30 (being positioned co-axially with and just in front of the dust cap of loudspeaker 23) functions as an acoustic lens or phase plug of sorts and more uniformly distributes the high frequency energy generated by loudspeaker driver 23. In addition, knob 30 includes printed indicia indicating to the user the transformer tap or power selection corresponding to the selected position of switch shaft 12. The curved or S-shaped support or strap bracket 29 fastened in front of loudspeaker driver 23 also can carry printed indicia indicating the power level selected or transformer taps selected for a given setting of switch 11.

Loudspeaker and switch assembly 10 has a small frontal area, as defined by circular grill 31, and that frontal area does not include a separate allocation of bezel area along one side, for example, to accommodate a level adjustment control on the side. Instead, the level adjustment control is within the peripheral edge of the driver diaphragm and is preferably coaxially integrated into a single and more compact assembly incorporating a back plate and pole piece having an axial bore, and a diaphragm or cone 38 having a dust cap 40 with an aperture aligned with the pole piece axial bore. As best seen in FIGS. 4 and 5, switch shaft 12 projects proximally toward the front of speaker 23 from the switch 11, which is mounted distally on the rear of magnet assembly 13. Cone 38 and dust cap 40 are aligned along the axis of the pole piece, as is customary in the art, but both cone 38 and dust cap 40 include axially aligned apertures sized to permit the proximal end of elongate switch shaft 12 to pass thru without contact, so that when cone 38 is energized and moves along the pole piece axis, there is no rubbing between either cone 38 or dust cap 40 and the static or unmoving switch shaft 12.

Enclosure or back can 22 includes a cover 28 secured by screws or other fasteners 33 and protects an input section for conduit runs with rigid or flex conduit and, optionally, a 4 pole detachable “phoenix” style connector 26 that allows easy pre-wiring and is convenient for daisy chaining additional speakers or subwoofers. “Press fit” grill 31 is releaseably attachable to the front or proximal end of enclosure 22 and is preferably contoured and finished to blend into contemporary architecture. An enhanced quality 70.7V/16W multi-tap internal transformer 27 is used to minimize insertion loss and maintain low frequency response while providing increased output for higher SPL applications. Optionally, loudspeaker driver 23 includes a weather/UV resistant polypropylene cone 38 with butyl rubber surround, contributing to even frequency response and coverage. The coaxial speaker/selector switch/tap indicator bracket assembly 29, 30 permits the footprint of the loudspeaker of the present invention 10 to be identical to that of a standard speaker having the same driver diameter. The tap selector switch control knob and tap indicator 30 is front mounted on the baffle assembly, allowing easy system tuning or balancing, for maintaining even coverage throughout the space.

In use, an installer is able to mount loudspeaker and switch assembly 10 in a very small space and adjust its loudness without dis-installing and reinstalling the loudspeaker driver, since access to the rear or side of back can 22 (the usual place for loudness adjusting knobs) isn't required. The loudspeaker and switch assembly 10 of the present invention can also be packed in very small spaces or very tightly packed arrays because no access is needed to the driver from the back in order to make the customary selections for a transformer tap or power line.

In the method of the present invention, an installer cuts or provides a suitably sized substantially circular aperture in partition 50 and then withdraws the electrical connection wires needed to connect the sound system to electrical connector 26 from the plenum or wall cavity. The installer can then, without activating the sound system or checking the speaker for loudness, install a loudspeaker into the cavity in the wall or plenum, next swinging dog like fastener 24 out to fasten the loudspeaker into the wall, ceiling or other plenum boundary surface, to grip the partition's distal surface 54. Once the loudspeaker has been installed and fixed in place, the installer or user can activate the sound system and adjust knob 30 (and therefore adjust switch 11) to select the appropriate transformer tap 27 and control the power dissipation in the loudspeaker, thereby controlling loudness. With the method of the present invention, the installer first installs the speaker into an aperture in partition 50 and can then adjust loudness without needing access to the back of the speaker (e.g., removing the speaker from the ceiling) in an iterative process which may require many dis-installations and re-installations before achieving the appropriate sound level (i.e., loudness or volume) from a given speaker. This feature is particularly useful in installations where it is inconvenient, difficult or unsafe to dis-install and re-install the speaker when attempting to properly adjust the loudness, especially in a small space, a dangerous location or for tightly packed arrays of several speakers in neighboring apertures, where having a small frontal area is important.

It will be appreciated that the present invention makes an easily installed and adjusted loudspeaker available. Loudspeaker and control switch assembly 10 is adapted for installation in partition 50 and subsequent adjustment and includes a loudspeaker driver 23 including a diaphragm or cone 38 suspended in a supporting flange structure proximate the driver proximal peripheral edge, the driver diaphragm 38 has a proximal surface and a central axis and includes a motor structure including a magnet assembly 13 and an axially aligned pole piece. Loudspeaker assembly 10 also has a control switch 11 connected to the loudspeaker and configured to control a signal passed to the loudspeaker driver 23, such that switch 11 is actuable using an elongate switch shaft 12 having a proximal end shaft passing through the pole piece and the driver diaphragm 38 so the shaft proximal end projects proximally beyond the driver diaphragm's proximal surface.

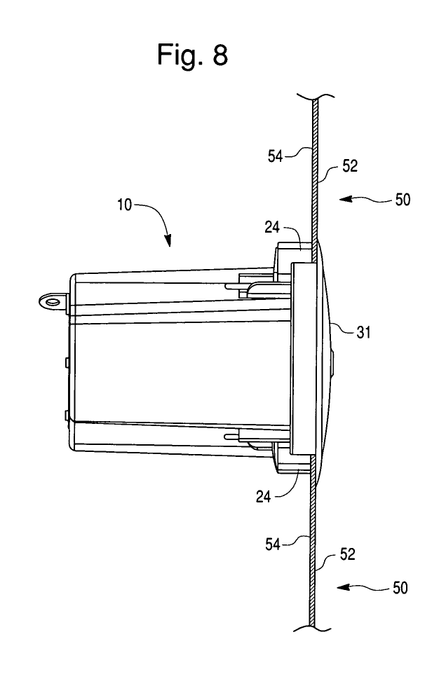

In accordance with the method for mounting and adjusting loudspeaker assembly 10 in a partition aperture, the method of the present invention preferably includes the method steps of providing a loudspeaker and signal controller housed within an enclosure 22 having a distal (or back) end opposing a proximal (or front) end; the loudspeaker includes a loudspeaker driver 23 with a diaphragm 38 having a proximal surface bounded by a peripheral edge, and the loudspeaker also includes a proximally projecting manipulable controller input or knob 30 supported within the driver peripheral edge and on the proximal side of the driver proximal surface (within the cone's periphery, as seen in FIG. 1). The loudspeaker enclosure 22 carries an electrical connector 26 adapted to receive an audio signal. Partition 50 has an aperture therethrough dimensioned to receive enclosure 22 and has a proximal surface 52 opposite a distal surface 54. An audio signal distribution system connection is accessible from the partition near the partition distal surface 54 and it is connected to the enclosure electrical connector 26. Next, the installer inserts enclosure 22 into the partition aperture (as shown in FIG. 8) to bring the enclosure proximal end flange into contact with the partition proximal surface, and the enclosure is fastened in place to the partition, preferably by swinging the dog-leg fasters our and into engagement with the partition distal surface.

Next, the audio signal distribution system connection is energized to provide an audio signal to loudspeaker driver 23; and then, without removing the enclosure from the partition aperture, the installer adjusts the audio playback of the loudspeaker driver by adjusting the proximally projecting manipulable controller input or knob 30.

Several loudspeaker assemblies can be mounted in corresponding numbers of apertures, where each first installed in its partition aperture and is then adjusted for playback level or power dissipation. The installer can then make system tuning or balancing adjustments to each loudspeaker assembly in an array of a plurality of loudspeakers, without having to dis-install any of the loudspeakers from their respective partition apertures.

A novel method for making an adjustable loudspeaker includes providing a loudspeaker driver 23 having a diaphragm 38 with a proximal (or front) surface bounded by a peripheral edge and a distal motor structure 13 including an axially aligned pole piece having an axially aligned aperture therethrough. An assembler then inserts a switch 11 carrying an elongate shaft 12 having a free end through the pole piece aperture to project proximally beyond the diaphragm's proximal surface; and mounts a manipulable controller input (e.g., knob 30) on the shaft free end such that it is supported within the driver peripheral edge and on the proximal side of the driver proximal surface (as best seen in FIGS. 1, 2 and 3).

Having described preferred embodiments of a new and improved loudspeaker structure and method, it is believed that other modifications, variations and changes will be suggested to those skilled in the art in view of the teachings set forth herein. It is therefore to be understood that all such variations, modifications and changes are believed to fall within the scope of the present invention, as set forth in the claims.

I claim:

1. A compact loudspeaker and control switch assembly adapted for installation in a partition and adjustment; comprising:
a loudspeaker driver including a diaphragm suspended in a supporting flange structure proximate the driver proximal peripheral edge, said driver diaphragm having a proximal surface and a central axis; said driver further including a motor structure including a magnet and an axially aligned pole piece; and
a control switch connected to said loudspeaker and configured to control a signal passed to the loudspeaker driver; said switch being actuable using an elongate switch shaft having a proximal end, said shaft passing through said pole piece and said driver diaphragm whereby said shaft proximal end projects proximally beyond said driver diaphragm proximal surface.

2. The compact loudspeaker and control switch assembly of claim 1, wherein said control switch is carried on a distal back plate of said motor structure.

3. The compact loudspeaker and control switch assembly of claim 1, wherein said control switch is configured to control the amplitude of said signal passed to the loudspeaker driver.

4. The compact loudspeaker and control switch assembly of claim 1, wherein, said control switch is configured to control the input power level of said signal passed to the loudspeaker driver.

5. The compact loudspeaker and control switch assembly of claim 4, wherein said control switch is configured to select one transformer tap among a plurality of available taps for controlling said signal passed to the loudspeaker driver.

6. The compact loudspeaker and control switch assembly of claim 1, wherein said control switch shaft proximal end carries an acoustic diffuser.

7. The compact loudspeaker and control switch assembly of claim 6, wherein said acoustic diffuser comprises a radiation uniformity enhancing phase plug.

8. The compact loudspeaker and control switch assembly of claim 1, further including a back can having a central axis that is coaxial with said driver central axis; said back can having a proximal opening adapted to receive said driver, wherein said driver is carried in said back can by the driver supporting flange peripheral edge;
said back can also having a solid side wall and a solid rear wall defining the back can exterior surface and carrying a plurality of electrically conductive connectors;
wherein said driver, said selector switch and a multi-tap transformer are enclosed within said back can;
wherein said switch and said driver are connected with at least one electrical conductor;
wherein said multi-tap transformer and said switch are connected with a plurality of electrical conductors; and
wherein said multi-tap transformer and said electrically conductive connectors are connected with at least one electrical conductor.

9. The compact loudspeaker and control switch assembly of claim 8, wherein said control switch shaft proximal end carries an input power level selector knob.

10. The compact loudspeaker and control switch assembly of claim 9, wherein said control switch is configured to select one transformer tap among a plurality of available taps for controlling said signal passed to the loudspeaker driver.

11. The compact loudspeaker and control switch assembly of claim 8, wherein said electrically conductive connectors comprise four conductive poles aligned in a linear array.

12. The compact loudspeaker and control switch assembly of claim 8, wherein said electrically conductive connectors are carried on a distal portion of said back can exterior surface.

13. The compact loudspeaker and control switch assembly of claim 8, wherein said back can exterior surface includes a proximal outwardly projecting peripheral flange.

14. The compact loudspeaker and control switch assembly of claim 14, wherein said back can exterior surface includes at least one swing-out fastener carried on said back can exterior surface proximate said proximal peripheral flange.

15. A method for installing and adjusting a loudspeaker in a partition, comprising the method steps of:
(a) providing a loudspeaker and signal controller housed within an enclosure having a distal end opposing a proximal end; said loudspeaker including a loudspeaker driver, said driver having a diaphragm with a proximal surface bounded by a peripheral edge, and said loudspeaker also including a proximally projecting manipulable controller input supported within said driver peripheral edge and on the proximal side of the driver proximal surface; said loudspeaker enclosure carrying an electrical connector adapted to receive an audio signal;
(b) providing a partition having an aperture therethrough; said aperture dimensioned to receive said enclosure and said partition having a proximal surface opposite a distal surface;
(c) providing an audio signal distribution system connection that is accessible from the partition aperture proximate the partition distal surface;
(d) connecting said audio signal distribution system connection to said enclosure electrical connector;
(e) inserting said enclosure into said partition aperture to bring said enclosure proximal end into contact with said partition proximal surface, and
(f) fastening said enclosure to said partition.

16. The method for installing and adjusting a loudspeaker in a partition of claim 15, further comprising the method step of:
(f) energizing said audio signal distribution system connection to provide an audio signal to said loudspeaker driver; and then, without removing said enclosure from said partition aperture,
(g) adjusting the audio playback of said loudspeaker driver by adjusting said proximally projecting manipulable controller input.

17. The method for installing and adjusting a loudspeaker in a partition of claim 16, further comprising the method steps of:
(h) providing a second loudspeaker and signal controller housed within a second enclosure having a distal end opposing a proximal end; said second loudspeaker including a second loudspeaker driver, said second driver having a diaphragm with a proximal surface bounded by a peripheral edge, and said second loudspeaker also including a second proximally projecting manipulable controller input supported within said second driver peripheral edge and on the proximal side of the driver proximal surface; said second loudspeaker enclosure carrying an electrical connector adapted to receive said audio signal;
(i) providing a second partition aperture through said partition; said second aperture dimensioned to receive said second enclosure;
(j) providing a second audio signal distribution system connection that is accessible from the second partition aperture proximate the partition distal surface;
(k) connecting said second audio signal distribution system connection to said second enclosure electrical connector;
(I) inserting said second enclosure into said second partition aperture to bring said second enclosure proximal end into contact with said partition proximal surface,
(m) fastening said second enclosure to said partition;
(n) energizing said audio signal distribution system second connection to provide said audio signal to said second loudspeaker driver; and then, without removing said second enclosure from said partition aperture;
(o) adjusting the audio playback of said second loudspeaker driver by adjusting said second proximally projecting manipulable controller input to balance the outputs of the first and second loudspeaker drivers without removing either the first or second enclosures from said partition.

18. The method for installing and adjusting a loudspeaker in a partition of claim 15, wherein step (f) fastening said enclosure to said partition, comprises:
(f1) swinging a first rotatable dog-leg retaining member out from a first position within the peripheral edge of said enclosure to a second position extending radially beyond the peripheral edge of said enclosure, to engage said partition distal surface

19. The method for installing and adjusting a loudspeaker in a partition of claim 18, further comprising:
(f2) swinging a second rotatable dog-leg retaining member spaced along the enclosure circumference from said first rotatable dog-leg retaining member out from a first position within the peripheral edge of said enclosure to a second position extending radially beyond the peripheral edge of said enclosure, to engage said partition distal surface.

20. A method for making an adjustable loudspeaker, comprising:
(a) providing a loudspeaker driver having a diaphragm with a proximal surface bounded by a peripheral edge and a distal motor structure including an axially aligned pole piece having an aperture therethrough,
(b) inserting a switch carrying an elongate shaft having a free end through said pole piece aperture to project proximally beyond said diaphragm proximal surface; and
(c) mounting a manipulable controller input on said shaft free end such that it is supported within said driver peripheral edge and on the proximal side of the driver proximal surface.
